(19) United States
(12) Patent Application Publication
(10) Pub. No.: US 2024/0234441 A1
(43) Pub. Date: Jul. 11, 2024

(54) DISPLAY SUBSTRATE AND DISPLAY APPARATUS

(71) Applicants: CHENGDU BOE DISPLAY SCI-TECH CO., LTD., Chengdu (CN); BOE Technology Group Co., Ltd., Beijing (CN)

(72) Inventors: Yong LIU, Beijing (CN); Wu WANG, Beijing (CN); Yanping LIAO, Beijing (CN); Zhangtao WANG, Beijing (CN); Mingzhi NAN, Beijing (CN); Xin HE, Beijing (CN); Xingkai FU, Beijing (CN)

(21) Appl. No.: 18/614,548

(22) Filed: Mar. 22, 2024

Related U.S. Application Data
(63) Continuation of application No. PCT/CN2022/128416, filed on Oct. 28, 2022.

(51) Int. Cl. H01L 27/12; G02F 1/1362

(52) U.S. Cl. CPC H01L 27/124; G02F 1/136286

(57) ABSTRACT

A display substrate and a display apparatus provided by the present disclosure include a plurality of pixels arranged in an array, where each of the pixels includes a plurality of sub-pixels, each of the sub-pixels includes a first domain area and a second domain area, and the first domain area and the second domain area each has at least two orientations; a plurality of data lines, where each of the data lines is electrically connected with first domain areas and second domain areas of a same column of sub-pixels; and a plurality of discharge wires, where each of the discharge wires is electrically connected with the second domain areas of the same column of the sub-pixels, and the discharge wires are configured for providing at least two direct current signals to two adjacent columns of pixels.

### CROSS-REFERENCE TO RELATED APPLICATIONS

The present disclosure is a continuation of International Application No. PCT/CN2022/128416, filed on Oct. 28, 2022, all of which is hereby incorporated by reference in its entirety.

### TECHNICAL FIELD

The present disclosure relates to the field of a display technology, and in particular, relates to a display substrate and a display apparatus.

### BACKGROUND

The liquid crystal display (LCD) has the advantages of light weight, low power consumption, high picture quality, low radiation and being easy to carry, etc. It has gradually replaced the traditional cathode ray tube display (CRT), and has been widely used in modern information devices, such as augmented reality (AR)/virtual reality (VR) display devices, laptops, TVs, mobile phones and digital products.

### SUMMARY

A display substrate and a display apparatus provided by the embodiments of the present disclosure have the following specific solutions.

On the one hand, the embodiments of the present disclosure provide a display substrate, including: a plurality of pixels arranged in an array, where each pixel includes a plurality of sub-pixels, each sub-pixel includes a first domain area and a second domain area, and the first domain area and the second domain area each has at least two orientations; a plurality of data lines, where each of the plurality of data lines is electrically connected with first domain areas and second domain areas of the same column of sub-pixels; and a plurality of discharge wires, where each of the plurality of discharge wires is electrically connected with the second domain areas of the same column of sub-pixels, and the plurality of discharge wires are configured to provide at least two direct current signals to two adjacent columns of pixels.

In some embodiments, in the above display substrate provided by the embodiments of the present disclosure, every at least two adjacent columns of sub-pixels are a cycle period, and the columns of sub-pixels within the same cycle period are electrically connected with discharge wires providing different direct current signals, respectively.

In some embodiments, in the above display substrate provided by the embodiments of the present disclosure, the plurality of discharge wires provide two different direct current signals; and every two adjacent columns of sub-pixels are a cycle period, and the two columns of sub-pixels in the same cycle period are electrically connected with discharge wires providing different direct current signals, respectively.

In some embodiments, in the above display substrate provided by the embodiments of the present disclosure, the plurality of discharge wires provide n different direct current signals, n is a total number of all sub-pixels in each pixel, and n is greater than or equal to 3; and all columns of sub-pixels in each column of pixels are a cycle period, and the columns of sub-pixels in the same cycle period are electrically connected with discharge wires providing different direct current signals, respectively.

In some embodiments, in the above display substrate provided by the embodiments of the present disclosure, the plurality of discharge wires provide 2 n different direct current signals, n is a total number of all sub-pixels in each pixel, and n is greater than or equal to 3; and all columns of sub-pixels in every two adjacent columns of pixels are a cycle period, and the columns of sub-pixels in the same cycle period are electrically connected with discharge wires providing different direct current signals, respectively.

In some embodiments, in the above display substrate provided by the embodiments of the present disclosure, the plurality of discharge wires provide two different direct current signals; and every two adjacent columns of pixels are a cycle period, the two columns of pixels in the same cycle period are electrically connected with discharge wires providing different direct current signals, and columns of sub-pixels in the same column of pixels are electrically connected with discharge wires providing the same direct current signal.

In some embodiments, in the above display substrate provided by the embodiments of the present disclosure, the data lines provide data signals with two polarities for columns of sub-pixels in the same column of pixels.

In some embodiments, the above display substrate provided by the embodiments of the present disclosure further includes at least two terminals, and the same terminal is electrically connected with discharge wires providing the same direct current signal.

In some embodiments, the above display substrate provided by the embodiments of the present disclosure further includes at least two filter circuits, and the filter circuits are connected between the at least two terminals and the discharge wires providing different direct current signals, respectively.

In some embodiments, in the above display substrate provided by the embodiments of the present disclosure, the filter circuit includes a resistor and a capacitor, where the resistor is connected between the terminal and the discharge wire, and the capacitor is connected between the discharge wire and ground.

In some embodiments, the above display substrate provided by the embodiments of the present disclosure further includes a gate line, where the second domain area includes a first transistor and a second transistor, a gate of the first transistor is electrically connected with the gate line, a first electrode of the first transistor is electrically connected with the data line, a second electrode of the first transistor is electrically connected with a first electrode of the second transistor, a gate of the second transistor is electrically connected with the gate line, and a second electrode of the second transistor is electrically connected with the discharge wire; and ratios of channel width-to-length ratios of first transistors to channel width-to-length ratios of second transistors in adjacent pixels or adjacent sub-pixels in a row direction are different.

In some embodiments, in the above display substrate provided by the embodiments of the present disclosure, in the adjacent pixels or the adjacent sub-pixels in the row direction, the channel width-to-length ratios of the first transistors are the same, and the channel width-to-length ratios of the second transistors are different.

On the other hand, the embodiments of the present application provide a display apparatus, including the above display substrate provided by the embodiment of the present disclosure.

### BRIEF DESCRIPTION OF FIGURES

FIG. 1 is a schematic diagram of a display substrate provided by embodiments of the present disclosure.

FIG. 2 is a schematic diagram of a multi-domain display light effect of the display substrate shown in FIG. 1.

FIG. 3 is a schematic structural diagram of the display substrate shown in FIG. 1.

FIG. 4 is an enlarged structural diagram of the Z region in FIG. 3.

FIG. 5 is yet another schematic diagram of a display substrate provided by embodiments of the present disclosure.

FIG. 6 is a schematic diagram of a multi-domain display light effect of the display substrate shown in FIG. 5.

FIG. 7 is yet another schematic diagram of a display substrate provided by embodiments of the present disclosure.

FIG. 8 is a schematic diagram of a multi-domain display light effect of the display substrate shown in FIG. 7.

FIG. 9 is yet another schematic diagram of a display substrate provided by embodiments of the present disclosure.

FIG. 10 is a schematic diagram of a multi-domain display light effect of the display substrate shown in FIG. 9.

FIG. 11 is yet another schematic diagram of a display substrate provided by embodiments of the present disclosure.

FIG. 12 is an equivalent circuit diagram of the display substrate shown in FIG. 3.

FIG. 13 is a schematic structural diagram of a display apparatus provided by embodiments of the present disclosure.

### DETAILED DESCRIPTION

In order to make the purposes, technical solutions and advantages of the embodiments of the present disclosure clearer, the technical solutions of the embodiments of the present disclosure will be clearly and completely described below in conjunction with drawings of the embodiments of the present disclosure. It should be noted that that the size and shape of each figure in the drawings do not reflect the true scale, but are only intended to illustrate the present disclosure. And the same or similar reference numerals represent the same or similar elements or elements having the same or similar functions throughout. To keep the following description of embodiments of the present disclosure clear and concise, the present disclosure omits detailed descriptions of known functions and known components.

Unless otherwise defined, technical or scientific terms used in the present disclosure shall have the ordinary meanings as understood by a person of ordinary skill in the art to which the present disclosure belongs. Words “first”, “second” and similar words used in the present disclosure do not indicate any order, quantity or importance, but are only used to distinguish different components. Word “comprise” or “include” or other similar words mean that the element or item appearing before the word encompasses the element or item listed after the word and its equivalents, but does not exclude other elements or items. Word “connection” or “coupling” or similar words are not limited to physical or mechanical connections, but may include electrical connections, whether direct or indirect. The terms “inside”, “outside”, “up”, “down”, etc., are used to indicate relative positional relationships, and when the absolute position of the described object changes, the relative positional relationship may change accordingly.

In the following description, when an element or layer is referred to be “on” or “connected to” another element or layer, the element or layer may be directly on another element or layer, or directly connected to another element or layer, or there may be an intermediate element or layer. When the element or layer is referred to be “provided at a side of” another element or layer, the element or layer may be directly at a side of another element or layer, or directly connected to another element or layer, or there may be an intermediate element or layer. However, when the element or layer is referred to be “directly on” another element or layer, or “directly connected to” another element or layer, there is no intermediate element or intermediate layer. The term “and/or” includes any and all combinations of one or more relevant listings.

With the progress of science and technology, the traditional single-domain liquid crystal display has been unable to meet the requirements of people on the liquid crystal display due to its shortcomings such as low contrast, asymmetric viewing angle, and color shift when viewing the display screen from different angles. Multi-domain display technology has gradually developed, and the so-called multi-domain display is that a sub-pixel is divided into different regions, different regions have different liquid crystal deflection degrees, and when watching the LCD screen from different angles, the comprehensive effect of the liquid crystal deflection in various regions is seen, thus reducing the contrast difference between different angles due to the same deflection of all liquid crystals within a pixel, thereby reducing the color shift, and increasing the viewing angle.

The more the number of the domains of a sub-pixel, the better the effect of the color shift, but the transmittance tends to reduce as the number of domains increases, so the design needs to be considered comprehensively to improve the color shift effect to the maximium while ensuring the transmittance. In order to improve the color shift effect, a sub-pixel is mostly designed with 8 domains in the related technology, specifically, the sub-pixel is divided into two parts, each of which is designed with 4 domains, but the pixel potentials of the two parts are different, and there is a difference in brightness and darkness (a bright pixel part is called a bright pixel, and a dark pixel part is called a dark pixel), so that the 8-domain display effect can be achieved. In the 8-domain display scheme, there are various ways to achieve the difference between the potentials of the bright and dark pixels, one of which is that each sub-pixel has three transistors, one transistor controls the bright pixel and two transistors control the dark pixel, the transistor controlling the bright pixel is electrically connected with a data line, and the two transistors controlling the dark pixel is electrically connected with a data line and a discharge wire respectively, so that the potential of the dark pixel is less than that of the bright pixel by the potential of the data line, the potential of the discharge wire, and the voltage dividing effect of the two transistors. However, all the sub-pixels are connected to the direct current signal with the same potential, resulting in almost no difference in the 8-domain display effect between different sub-pixels, and the adjustable range is limited when the color shift effect is poor.

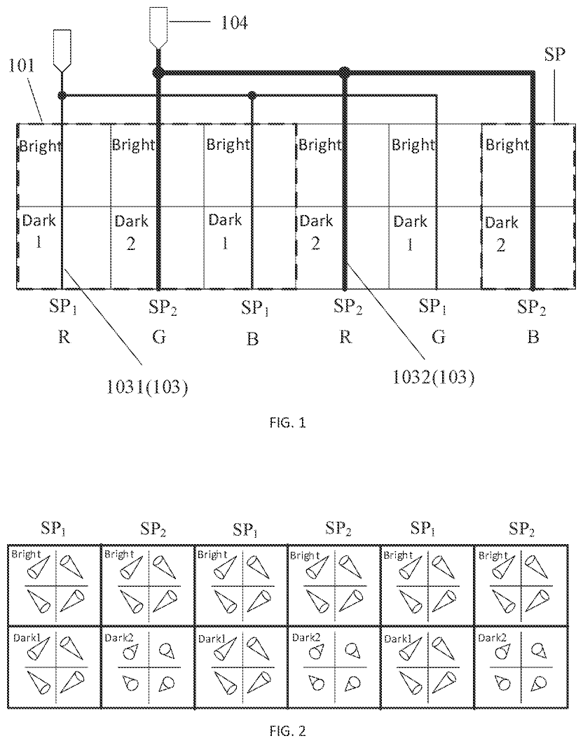

To ameliorate the above technical problems existing in the related technology, embodiments of the present disclosure provide a display substrate, as shown in FIGS. 1-2, including:

a plurality of pixels 101 arranged in an array, herein, each pixel 101 includes a plurality of sub-pixels SP, each sub-pixel SP includes a first domain area (e.g., a bright pixel) and a second domain area (e.g., a dark pixel), and the first domain area (e.g., the bright pixel) and the second domain area (e.g., the dark pixel) each has at least two orientations;

a plurality of data lines 102, herein, each data line 102 is electrically connected with first domain areas (e.g., the bright pixel) and second domain areas (e.g., the dark pixel) of the same column of sub-pixels SP; and
a plurality of discharge wires 103, herein, each discharge wire 103 is electrically connected with second domain areas (e.g., a dark pixel) of the same column of sub-pixels SP, and the discharge wires 103 provide at least two direct current (DC) signals of different amplitudes to two adjacent columns of pixels 101. Optionally, the DC signals of the discharge wires 103 in the present disclosure may be greater than 0 and less than or equal to 15V, for example, 5V, 8V, 9V, and the like.

In the above display substrate provided by embodiments of the present disclosure, when two adjacent columns of pixels 101 are connected to at least two DC signals of different amplitudes, the second domain areas (e.g., dark pixels) of the two adjacent columns of pixels 101 can be made to present at least two multi-domain display effects, which can be approximately equivalent to increasing the number of domains, and thus the color shift can be better improved.

In some embodiments, the total number of orientations of the first domain area (e.g., a bright pixel) may be the same as the total number of orientations of the second domain area (e.g., a dark pixel), for example, the first domain area (e.g., the bright pixel) and the second domain area (e.g., the dark pixel) in FIG. 2 each has four orientations. In other embodiments, the total number of orientations of the first domain area (e.g., the bright pixel) and the total number of orientations of the second domain area (e.g., the dark pixel) may be different. For example, the first domain area (e.g., the bright pixel) has two orientations and the second domain area (e.g., the dark pixel) has four orientations. Of course, the total number of orientations of the first domain area (e.g., the bright pixel) and the total number of orientations of the second domain area (e.g., the dark pixel) are not limited to two or four, but may be other numbers (e.g., three), which are not limited herein.

In some embodiments, in the above display substrate provided by embodiments of the present disclosure, as shown in FIGS. 1 to 8, every at least two adjacent columns of sub-pixels SP are a cycle period, and columns of the sub-pixels SP within the same cycle period are electrically connected with discharge wires 103 providing different DC signals, respectively, so that the multi-domain display effects of the second domain areas (e.g., the dark pixels) of various columns of sub-pixels SP within the same cycle period are different, which can be approximately equivalent to increasing the number of domains, and thus the color shift can be better improved. Optionally, the discharge wires 103 respectively connected to the columns of the sub-pixels SP corresponding to the same position in various cycle periods may converge together, to save the number of terminals providing signals to the discharge wires 103.

In some embodiments, as shown in FIG. 1, the plurality of discharge wires 103 provide two different DC signals; and every two adjacent columns of sub-pixels SP are a cycle period, and the two columns of sub-pixels SP within the same cycle period are electrically connected with the discharge wires 103 providing the different DC signals, respectively. For ease of understanding, the discharge wires 103 corresponding to the two different DC signals are respectively marked in FIG. 1 as a first discharge wire 1031 and a second discharge wire 1032, and the two columns of sub-pixels SP within the same cycle period are marked as a first column of sub-pixels SP₁ and a second column of sub-pixels SP₂, respectively. The first column of sub-pixels SP₁ is electrically connected with the first discharge wire 1031 and the second column of sub-pixels SP₂ is electrically connected with the second discharge wire 1032. Based on this embodiment, as shown in FIG. 2, because the DC signal provided by the first discharge wire 1031 is different from the DC signal provided by the second discharge wire 1032, the second domain areas (e.g., dark pixels) in the first column of sub-pixels SP₁ present one multi-domain display effect, and the second domain areas (e.g., dark pixels) in the second column of sub-pixels SP₂ present another multi-domain display effect. Compared to the related technology in which the second domain areas (e.g., the dark pixels) in the first column of sub-pixels SP₁ and the second domain areas (e.g., the dark pixels) in the second column of sub-pixels SP₂ have a similar dark state multi-domain display effect, the present disclosure effectively enriches the multi-domain display effect, and is more conducive to improving the color shift.

In some embodiments, in the above display substrate provided by embodiments of the present disclosure, as shown in FIGS. 5-6, a plurality of discharge wires 103 provide n different DC signals, n is the total number of sub-pixels in each pixel, and n is greater than or equal to 3; and columns of the sub-pixels SP in each column of pixels P are a cycle period, and various columns of sub-pixels SP within the same cycle period are electrically connected with the discharge wires 103 that provide different DC signals, respectively. For ease of understanding, FIG. 5 is illustrated with an example that each column of pixels P has three columns of sub-pixels SP (e.g., a column of red sub-pixels R, a column of green sub-pixels G, and a column of blue sub-pixels B, respectively), and the plurality of discharge wires 103 provide three types of DC signals. Exemplarily, the discharge wires 103 corresponding to the three types of DC signals in FIG. 5 are respectively marked as a first discharge wire 1031, a second discharge wire 1032 and a third discharge wire 1033, and the three columns of sub-pixels SP in the same cycle period are marked as a first column of sub-pixels SP₁, a second column of sub-pixels SP₂ and a third column of sub-pixels SP3, respectively. Here, the first column of sub-pixels SP₁ is electrically connected with the first discharge wire 1031, the second column of sub-pixels SP₂ is electrically connected with the second discharge wire 1032, and the third column of sub-pixels SP₃ is electrically connected with the third discharge wire 1033. Based on this embodiment, as shown in FIG. 6, since the DC signal provided by the first discharge wire 1031, the DC signal provided by the second discharge wire 1032, and the DC signal provided by the third discharge wire 1033 are different, the second domain areas (e.g., the dark pixels) in the first column of sub-pixels SP₁ present a first multi-domain display effect, the second domain areas (e.g., the dark pixels) in the second column of sub-pixels SP₂ present a second multi-domain display effect, and the second domain areas (e.g., the dark pixels) in the third column of sub-pixels SP₃ present a third multi-domain display effect. Compared to the related technology in which the second domain areas (e.g., the dark pixels) in the first column of sub-pixels SP₁, the second domain areas (e.g., the dark pixels) in the second column of sub-pixels SP₂, and the second domain areas (e.g., the dark pixels) in the third column of sub-pixels SP₃ present a similar dark state multi-domain display effect, the present embodiment further enriches the multi-domain display effect and is more conducive to improving the color shift. Moreover, the embodiment also achieves separate control of the multi-domain display effects of the red sub-pixels R, the green sub-pixels G, and the blue sub-pixels B.

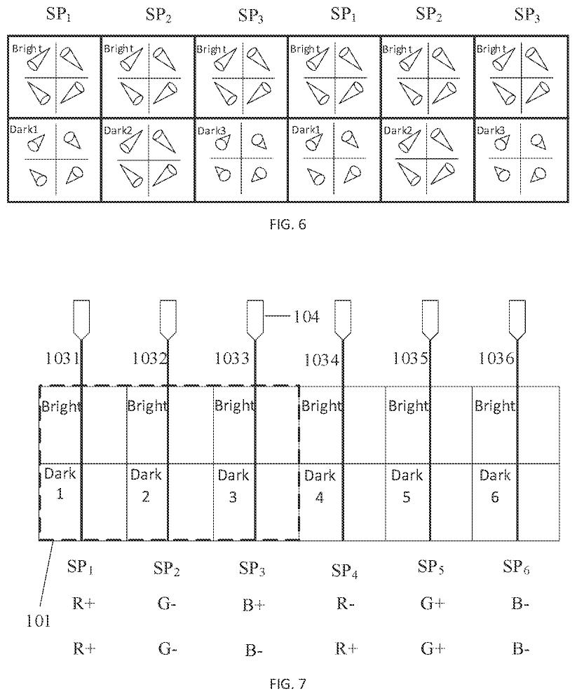

In some embodiments, in the above display substrate provided by embodiments of the present disclosure, as shown in FIGS. 7-8, the plurality of discharge wires 103 provide 2 n different DC signals, n is the total number of sub-pixels SP in each pixel 101, and n is greater than or equal to 3; and columns of the sub-pixels SP in every two adjacent columns of pixels 101 are a cycle period, and the columns of sub-pixels SP within the same cycle period are electrically connected with the discharge wires 103 providing different DC signals, respectively. For ease of understanding, FIG. 7 is illustrated with an example that each column of pixels P has three columns of sub-pixels SP (e.g., a column of red sub-pixels R, a column of green sub-pixels G, and a column of blue sub-pixels B, respectively), and the plurality of discharge wires 103 provide six types of DC signals. Exemplarily, the discharge wires 103 corresponding to the six types of DC signals in FIG. 7 are respectively marked as a first discharge wire 1031, a second discharge wire 1032, a third discharge wire 1033, a fourth discharge wire 1034, a fifth discharge wire 1035 and a sixth discharge wire 1036; and the six columns of sub-pixels SP in the same cycle period are marked as a first column of sub-pixels SP₁, a second column of sub-pixels SP₂, a third column of sub-pixels SP₃, a fourth column of sub-pixels SP₄, a fifth column of sub-pixels SP₅, and a sixth column of sub-pixels SP₆, respectively. Here, the first column of sub-pixels SP₁ is electrically connected with the first discharge wire 1031, the second column of sub-pixels SP₂ is electrically connected with the second discharge wire 1032, the third column of sub-pixels SP₃ is electrically connected with the third discharge wire 1033, the fourth column of sub-pixels SP₄ is electrically connected with the fourth discharge wire 1034, the fifth column of sub-pixels SP₅ is electrically connected with the fifth discharge wire 1035, and the sixth column of sub-pixels SP₆ is electrically connected with the sixth discharge wire 1036. Based on this embodiment, as shown in FIG. 8, because the DC signal provided by the first discharge wire 1031, the DC signal provided by the second discharge wire 1032, the DC signal provided by the third discharge wire 1033, the DC signal provided by the fourth discharge wire 1034, the DC signal provided by the fifth discharge wire 1035, and the DC signal provided by the sixth discharge wire 1036 are all different, the second domain areas (e.g., the dark pixels) in the first column of sub-pixels SP₁ present a first multi-domain display effect, the second domain areas (e.g., the dark pixels) in the second column of sub-pixels SP₂ present a second multi-domain display effect, the second domain areas (e.g., the dark pixels) in the third column of sub-pixels SP₃ present a third multi-domain display effect, the second domain areas (e.g., the dark pixels) in the fourth column of sub-pixels SP₄ present the first multi-domain display effect, the second domain areas (e.g., the dark pixels) in the fifth column of sub-pixels SP₅ present the second multi-domain display effect, and the second domain areas (e.g., the dark pixels) in the sixth column of sub-pixels SP₆ present the third multi-domain display effect. Compared to the related technology in which the second domain areas (e.g., the dark pixels) in the first column of sub-pixels SP₁, the second domain areas (e.g., the dark pixels) in the second column of sub-pixels SP₂, the second domain areas (e.g., the dark pixels) in the third column of sub-pixels SP₃, the second domain areas (e.g., the dark pixels) in the fourth column of sub-pixels SP₄, the second domain areas (e.g., the dark pixels) in the fifth column of sub-pixels SP₅, and the second domain areas (e.g., the dark pixels) in the sixth column of sub-pixels SP₆ present a similar dark state multi-domain display effect, the present embodiment further enriches the multi-domain display effect, and is more conducive to improving the color shift.

In some embodiments, the data lines 102 provide data signals with two polarities for various columns of sub-pixels SP in the same column of pixels 101. Continuing to refer to FIG. 7, it can be seen that one column of pixels 101 includes three columns of sub-pixels SP, and the three columns of sub-pixels SP can be loaded with two data signals of the positive polarity (+) and one data signal of the negative polarity (−), or, the three columns of sub-pixels SP can be loaded with two data signals of the negative polarity and one data signal of the positive polarity. Exemplarily, during a cycle period shown in FIG. 7, the first column of sub-pixels SP₁, the second column of sub-pixels SP₂, the third column of sub-pixels SP₃, the fourth column of sub-pixels SP₄, the fifth column of sub-pixels SP₅, and the sixth column of sub-pixels SP₆ in the two columns of pixels 101 may be respectively loaded with a data signal of the positive polarity, a data signal of the negative polarity, a data signal of the positive polarity, a data signal of the negative polarity, a data signal of the positive polarity and a data signal of the negative polarity, or may be respectively loaded with a data signal of the positive polarity, a data signal of the negative polarity, a data signal of the negative polarity, a data signal of the positive polarity, a data signal of the positive polarity, and a data signal of the negative polarity. In this embodiment, not only can the multi-domain display effects of the red sub-pixels R, the green sub-pixels G and the blue sub-pixels B be separately controlled, but also separate control of the sub-pixels SP loaded with the data signal of the positive polarity and the data signal of the negative polarity is achieved.

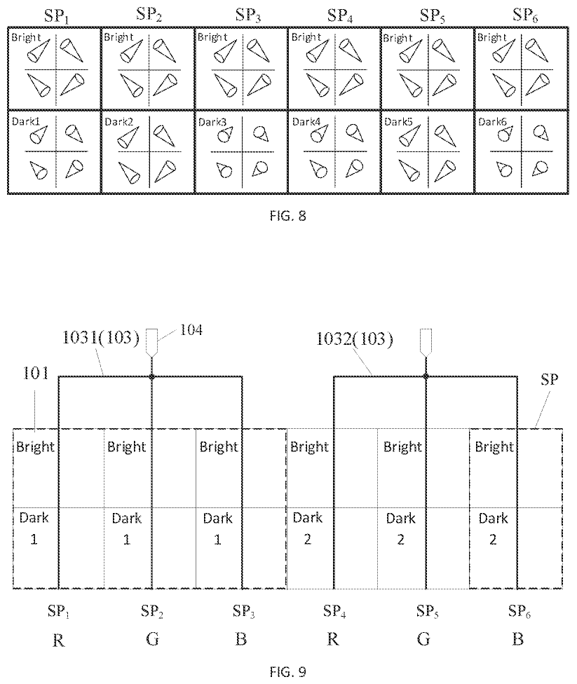

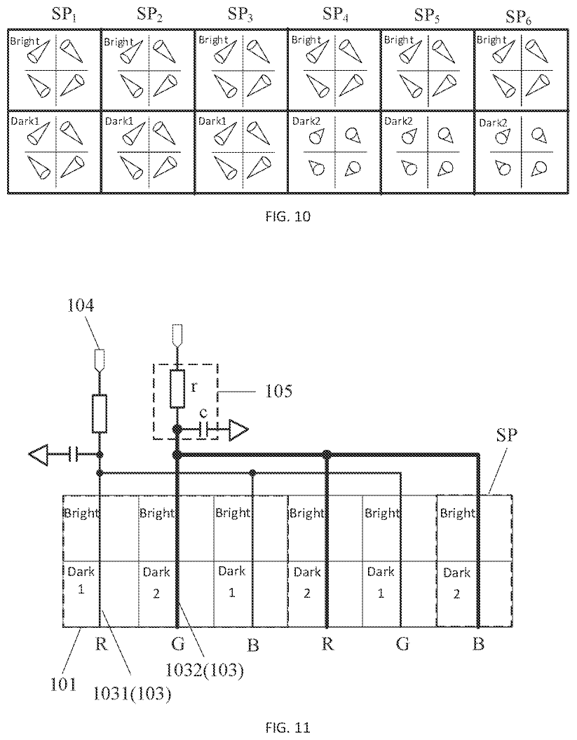

In some embodiments, in the above display substrate provided by embodiments of the present disclosure, as shown in FIGS. 9-10, the plurality of discharge wires 103 provide two different DC signals; and every two adjacent columns of pixels 101 are a cycle period, the two columns of pixels 101 in the same cycle period are electrically connected with the discharge wires 103 providing different DC signals, and various columns of sub-pixels SP in the same column of pixels 101 are electrically connected with the discharge wires 103 providing the same DC signals. For ease of understanding, FIG. 9 illustrates an example that each column of pixels 101 has three columns of sub-pixels SP (e.g., a column of red sub-pixels R, a column of green sub-pixels G, and a column of blue sub-pixels B, respectively). Exemplarily, the discharge wires 103 corresponding to the two type of DC signals in FIG. 9 are respectively marked as a first discharge wire 1031 and a second discharge wire 1032, and various columns of sub-pixels SP in the two columns of pixels 101 in the same cycle period are respectively marked as a first column of sub-pixels SP₁, a second column of sub-pixels SP₂, a third column of sub-pixels SP₃, a fourth column of sub-pixels SP₄, a fifth column of sub-pixels SP₅ and a sixth column of sub-pixels SP₆. Here, the first column of sub-pixels SP₁, the second column of sub-pixels SP₂ and the third column of sub-pixels SP₃ in one of the columns of pixels 101 are electrically connected with the first discharge wires 1031; and the fourth column of sub-pixels SP₄, the fifth column of sub-pixels SP₅ and the sixth column of sub-pixels SP₆ in the other column of pixels 101 are electrically connected with the second discharge wires 1032. Based on this embodiment, as shown in FIG. 10, because the DC signal provided by the first discharge wire 1031 is different from the DC signal provided by the second discharge wire 1032, the second domain areas (e.g., the dark pixels) in the first column of sub-pixels SP₁, the second domain areas (e.g., the dark pixels) in the second column of sub-pixels SP₂, and the second domain areas (e.g., the dark pixels) in the third column of sub-pixels SP₃ present one multi-domain display effect; and the second domain areas (e.g., the dark pixels) in the fourth column of sub-pixels SP₄, the second domain areas (e.g., the dark pixels) in the fifth column of sub-pixels SP₅, and the second domain areas (e.g., the dark pixels) in the sixth column of sub-pixels SP₆ present another multi-domain display effect. Compared to the related technology in which the second domain areas (e.g., the dark pixels) in the first column of sub-pixels SP₁, the second domain areas (e.g., the dark pixels) in the second column of sub-pixels SP₂, the second domain areas (e.g., the dark pixels) in the third column of sub-pixels SP₃, the second domain areas (e.g., the dark pixels) in the fourth column of sub-pixels SP₄, the second domain areas (e.g., the dark pixels) in the fifth column of sub-pixels SP₅, and the second domain areas (e.g., the dark pixels) in the sixth column of sub-pixels SP₆ present a similar dark state multi-domain display effect, the present embodiment effectively enriches the multi-domain display effect by controlling the pixels 101 in the odd and even columns separately, thereby facilitating the improvement of the color shift.

It should be noted that the types of DC signals ranging from 2 to 6 are used as examples for illustration in the disclosure, and different numbers of DC signals can be selected according to different needs. Moreover, the DC signals in the present disclosure are DC signals similar to the common voltage signals. Under normal cases, 6 different amplitudes of DC signals are sufficient for use, and in a case of too many DC signals, it will be difficult to control and will increase the cost. Therefore, the present disclosure is only illustrated by examples with 6 types of DC signals or fewer DC signals. However, in some embodiments, more (e.g., 7 or more) different amplitudes of DC signals may be provided, which is not limited herein. In addition, the columns of the sub-pixels SP or the columns of the pixels 101 electrically connected with the discharge wires 103 providing the different DC signals are arranged alternately in the present disclosure, so that the overall multi-domain display effect is uniform after combining the multi-domain display effect formed in the first domain areas (e.g., the bright pixels) with the second domain areas (e.g., the dark pixels) in which two different multi-domain display effects are formed in a relatively small range, and there is no split-screen phenomenon.

In some embodiments, the above display substrate provided by embodiments of the present disclosure, as shown in FIG. 11, may further include at least two terminals 104, and the same terminal 104 is electrically connected with discharge wires 103 providing the same DC signal, to uniformly load signals for various discharge wires 103 providing the same DC signal through the same terminal 104, facilitating the reduction of the number of terminals 104. Continuing to refer to FIG. 11, the present disclosure may further include at least two filter circuits 105, which are respectively connected between the at least two terminals 104 and the discharge wires 103 providing different DC signals, so as to ensure that the DC signals with a fixed potential on the discharge wires 103 are more stable and reliable through the filter circuits 105, and to reduce the interference of the alternating current (AC) signals on the data lines 102 to the DC signals on the discharge wires 103. Optionally, as shown in FIG. 11, the filter circuit 105 may include a resistor r and a capacitor c; and the resistor r is connected between the terminal 104 and the discharge wire 103, and the capacitor c is connected between the discharge wire 103 and the ground. The structure of this filter circuit 105 is relatively simple and requires the less layout space, which is conducive to the narrow bezel design of a product. Of course, in some embodiments, the filter circuit 105 may also have other structures known to those skilled in the art, and is not specifically limited herein.

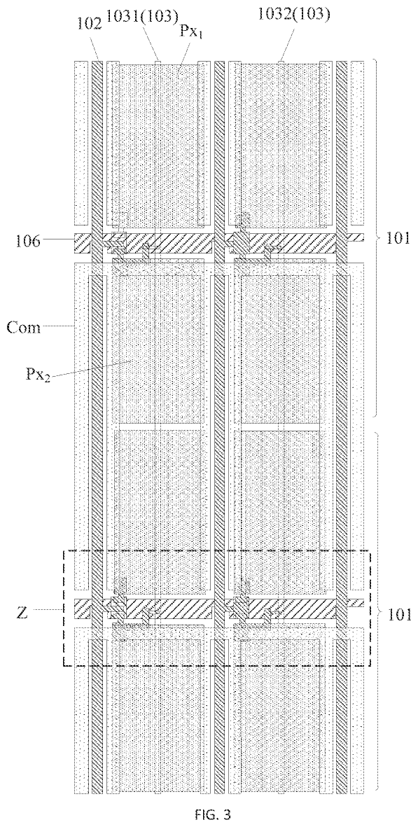

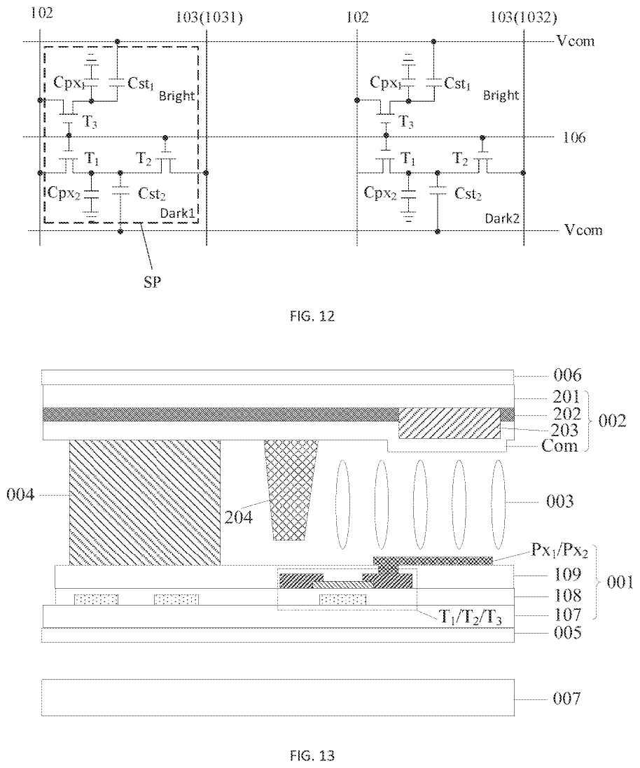

In some embodiments, the above display substrate provided by embodiments of the present disclosure, as shown in FIGS. 3-4 and FIG. 12, may further include a gate line 106, the second domain area (e.g., the dark pixel) includes a first transistor T₁ and a second transistor T₂, a gate of the first transistor T₁ is electrically connected with the gate line 106, a first electrode of the first transistor T₁ is electrically connected with the data line 102, a second electrode of first transistor T₁ is electrically connected with a first electrode of the second transistor T₂, a gate of the second transistor T₂ is electrically connected with the gate line 106, and a second electrode of the second transistor T₂ is electrically connected with the discharge wire 103. In adjacent sub-pixels SP or adjacent pixels 101 in a row direction, ratios of channel width-to-length ratios of first transistors T₁ to channel width-to-length ratios of second transistors T₂ are different. The first transistor T₁ and the second transistor T₂ connected between the data line 102 and the discharge wire 103 may be equivalent to two resistors, and ideally the potential of the first domain area (e.g., the bright pixel) and the potential of the second domain area (e.g., the dark pixel) may be converted via a potential of the data line 102, a potential of the discharge wire 103, and a resistive divider voltage formula of the first transistor T₁ and the second transistor T₂. For example, if the ratio of the channel width-to-length ratio of the first transistor T₁ to the channel width-to-length ratio of the second transistor T₂ (which may be equated to the resistance ratio of the two) is 1:1, the potential of the data signal of the data line 102 is 10 y, and the potential of the DC signal of the discharge wire 103 is 5V, through the resistive divider voltage formula, the potential of the second domain area (e.g., the dark pixel) is 7.5V, and the potential of the first domain area (e.g., the bright pixel) is equal to the potential of the data line 102, which is 10V. So that there is a voltage difference of 2.5V between the first domain area (e.g., the bright pixel) and the second domain area (e.g., the dark pixel), which presents the multi-domain display effects with different brightness and darkness. In the case where the ratios of the channel width-to-length ratios of the first transistors T₁ to the channel width-to-length ratios of the second transistors T₂ in the second domain areas (e.g., the dark pixels) of the adjacent pixels 101 or the adjacent sub-pixels SP are different, the second domain areas (e.g., the dark pixels) of the adjacent pixels 101 or sub-pixels SP may present different multi-domain display effects, which is conducive to improving the color shift. When combined with the discharge wires 103 that provide different DC signals, the multi-domain display effects of the different DC signals can be more fully exploited, and the color shift can be better improved.

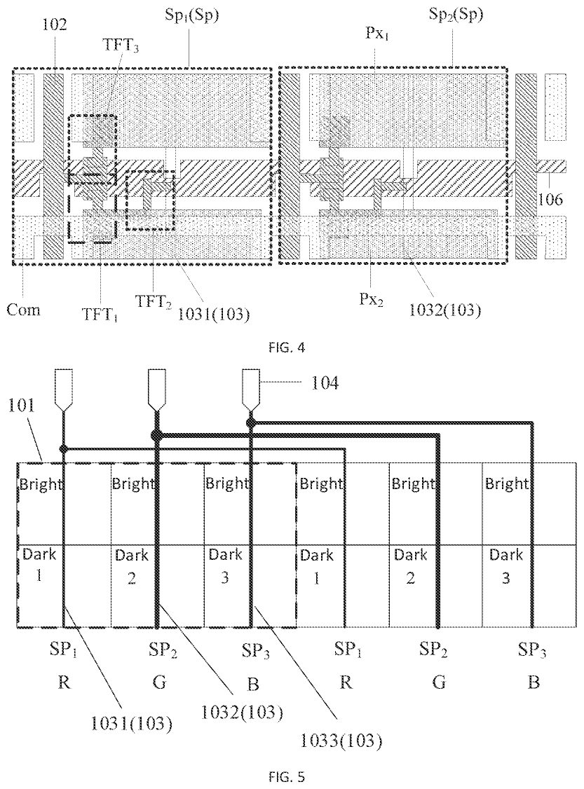

In some embodiments, in order to form a better multi-domain display effect, the ratio of the channel width-to-length ratio of the first transistor T₁ to the channel width-to-length ratio of the second transistor T₂ may be in the range of 1 to 5. Optionally, the first transistor T₁ and the second transistor T₂ may be oxide (e.g., indium gallium zinc oxide (IGZO)) transistors, and the channel width-to-length ratio of the first transistor T₁ and the channel width-to-length ratio of the second transistor T₂ may be in the range of 1:4 to 1:1. For example, the channel width of the first transistor T₁ and the channel width of the second transistor T₂ are 5 μm, the channel length of the first transistor T₁ and the channel length of the second transistor T₂ are in the range of 5 μm to 20 μm, and correspondingly the channel width-to-length ratio is in the range of 5/20 to 5/5 ; or, the channel width of the first transistor T₁ and the channel width of the second transistor T₂ are 3 μm, the channel length of the first transistor T₁ and the channel length of the second transistor T₂ are in the range of 3 μm to 12 μm, and correspondingly the channel width-to-length ratio is in the range of 3/12 to 3/3. Optionally, the first transistor T₁ and the second transistor T₂ may also be amorphous silicon (a-Si) transistors, and the channel width-to-length ratio of the first transistor T₁ and the channel width-to-length ratio of the second transistor T₂ may be in the range of 3:5 to 10:3. For example, the channel length of the first transistor T₁ and the channel length of the second transistor T₂ are 5 μm, the channel width of the first transistor T₁ and the channel width of the second transistor T₂ are in the range of 3 μm to 10 μm, and correspondingly the channel width-to-length ratio is in the range of 3/5 to 10/5; or, the channel length of the first transistor T₁ and the channel length of the second transistor T₂ are 3 μm, the channel width of the first transistor T₁ and the channel width of the second transistor T₂ are in the range of 3 μm to 10 μm, and correspondingly the channel width-to-length ratio is in the range of 3/3 to 10/3. It is to be noted that the channel width-to-length ratio of the transistor is not limited by the shape of an active layer, and thus the active layer of the transistor may be I-shaped as shown in FIGS. 3-4, or may be U-shaped, L-shaped, and the like.

In some embodiments, in the above display substrate provided by embodiments of the present disclosure, in order to ensure that the ratios of the channel width-to-length ratios of the first transistors T₁ to the channel width-to-length ratios of the second transistors T₂ in the adjacent sub-pixels SP or adjacent pixels 101 in the row direction are different, and the design of the transistors is simplified, the channel width-to-length ratios of the first transistors T₁ may be the same, and the channel width-to-length ratios of the second transistor T₂ may be different. In other words, the ratios of the channel width-to-length ratios of the first transistors T₁ to the channel width-to-length ratios of the second transistors T₂ in the adjacent sub-pixels SP or the adjacent pixels 101 can be different by adjusting the channel width-to-length ratios of the second transistors T₂ in the adjacent sub-pixels SP or the adjacent pixels 101, so it is not necessary to adjust the channel width-to-length ratios of the first transistors T₁ and the channel width-to-length ratios of the second transistors T₂ at the same time to achieve the purpose of different ratios.

In some embodiments, in the above display substrate provided in embodiments of the present disclosure, as shown in FIGS. 3-4 and FIG. 12, the first domain area (e.g., the bright pixel) may include a third transistor T₃, a first storage capacitor Cst₁, a first liquid crystal capacitor Cpx₁ formed by a first pixel electrode Px₁ and a common electrode Com (which may be disposed on the opposing substrate CF); and the second domain area (e.g., the dark pixel) further may include a second storage capacitor Cst₂, and a second liquid crystal capacitor Cpx₂ formed by a second pixel electrode Px₂ with a common electrode Com. Here, a gate of the third transistor T₃ is electrically connected with the gate line 106, a first electrode of the third transistor T₃ is electrically connected with the data line 102, a second electrode of the third transistor T₃ is electrically connected with the first pixel electrode Px₁ and one end of the first storage capacitor Cst₁, and the other end of the first storage capacitor Cst₁ is electrically connected with the common electrode line Vcom; and the second pixel electrode Px₂ and one end of the second storage capacitor Cst₂ are connected with the connection position between the second electrode of the first transistor T₁ and the first electrode of the second transistor T₂, and the other end of the second storage capacitor Cst₂ is electrically connected with the common electrode line Vcom. Other elements known to those skilled in the art in the first domain area (e.g., the bright pixel) and the second domain area (e.g., the dark pixel) are not described herein and are not intended to limit the present disclosure.

Based on the same inventive concept, the embodiments of the present disclosure provide a display apparatus including the above display substrate provided by the embodiments of the present disclosure. Since a principle of the display device for solving a problem is similar to the principle of the above display substrate for solving the problem, an implementation of the display apparatus provided by the embodiments of the present disclosure may refer to the implementation of the above display substrate provided by the embodiments of the present disclosure, and repetitions are omitted.

In some embodiments, as shown in FIG. 13, the above display apparatus provided by the embodiments of the present disclosure may further include an opposing substrate 002 opposing to the display substrate 001, a liquid crystal layer 003 disposed between the display substrate 001 and the opposing substrate 002, a sealant 004 enclosing the liquid crystal layer 003 between the display substrate 001 and the opposing substrate 002, a first polarizer 005 located at a side of the display substrate 001 away from the liquid crystal layer 003, a second polarizer 006 located at a side of the opposing substrate 002 away from the liquid crystal layer 003, and a backlight module 007 located at a side of the first polarizer 005 away from the display substrate 001. Optionally, the opposing substrate 002 may include a first base substrate 201, a black matrix 202, a color resist 203, a spacer 204 and a common electrode Com. The display substrate includes transistors (including but not limited to a first transistor T₁, a second transistor T₂, and a third transistor T₃), a second base substrate 107, a gate insulating layer 108, a passivation layer 109, and the like.

In some embodiments, the backlight module 007 may be a direct-lit backlight module or an edge-lit backlight module. Optionally, the edge-lit backlight module may include a light bar, reflective sheets that are stacked, a light guide plate, a diffusion sheet, a prism group, etc.. The light bar is located at a side of the light guide plate in a thickness direction. The direct-lit backlight module may include a matrix light source, reflective sheets that are stacked on a light emitting side of the matrix light source, a diffusion plate, a brightness enhancement film, etc.. The reflective sheet includes an opening arranged directly facing a position of each lamp bead in the matrix light source. The lamp beads in the light bar and the lamp beads in the matrix light source may be light emitting diodes (LEDs), such as mini LEDs, micro LEDs, or the like.

Like organic light-emitting diodes (OLEDs), sub-millimetre or even micrometre-scale micro LEDs belong to self-luminous devices. Like organic light-emitting diodes, they have a series of advantages such as high brightness, ultra-low delay, and extra-large viewing angle. Moreover, an inorganic light emitting diode emits light on the basis of a metal semiconductor having the more stable properties and lower resistance, such that the inorganic light emitting diode has the lower power consumption, the higher resistance to high and low temperatures and the longer service life than an organic light emitting diode that emits light on the basis of organic substances. When a micro light emitting diode is used as a backlight source, a more precise dynamic backlight effect can be achieved, brightness and contrast of a screen can be effectively improved, and meanwhile, a glare phenomenon caused by traditional dynamic backlight between bright and dark regions of the screen can be avoided, which optimizes visual experience.

In some embodiments, the above display apparatus provided by the embodiments of the present disclosure may be any product or component with a display function such as a projector, a 3D printer, a virtual reality device, a mobile phone, a tablet computer, a television set, a monitor, a laptop computer, a digital photo frame, a navigator, a smart watch, a fitness wristband, a personal digital assistant. The display apparatus includes, but is not limited to, components such as a radio frequency unit, a network module, an audio output & input unit, a sensor, a display unit, a user input unit, an interface unit, and a control chip. Optionally, the control chip is a central processing unit, a digital signal processor, a system-on-chip (SoC), or the like. For example, the control chip may further include a memory, and may further include a power supply module and the like, and functions of the power supply as well as the signal input and output are realized via additionally provided wires, cables and the like. For example, the control chip may also include a hardware circuit, computer executable code, and the like. The hardware circuit may include a conventional very large scale integration (VLSI) circuit or a gate arrays as well as existing semiconductors such as a logic chip and a transistor, or other discrete components; and the hardware circuit may further include a field programmable gate array, a programmable array logic, a programmable logic device, and the like. In addition, those skilled in the art can understand that the above structure does not limit the display apparatus according to the embodiments of the present disclosure. That is, the display apparatus according to the embodiments of the present disclosure may include more or less components, or combine some components, or have different component arrangements.

Although the present disclosure describes preferred embodiments, it should be understood that those skilled in the art can make various modifications and variations to the embodiments of the present disclosure without departing from the spirit and scope of the embodiments of the present disclosure. In this way, if these modifications and variations of the embodiments of the present disclosure fall within the scope of the claims of the present disclosure and their equivalent technologies, the present disclosure is also intended to involve these modifications and variations.

What is claimed is:

1. A display substrate, comprising:
a plurality of pixels arranged in an array, wherein each of the plurality of pixels comprises a plurality of sub-pixels, each of the plurality of sub-pixels comprises a first domain area and a second domain area, and the first domain area and the second domain area each has at least two orientations;
a plurality of data lines, wherein each of the plurality of data lines is electrically connected with first domain areas and second domain areas of a same column of sub-pixels; and
a plurality of discharge wires, wherein each of the plurality of discharge wires is electrically connected with the second domain areas of the same column of sub-pixels, and the plurality of discharge wires are configured to provide at least two direct current signals to two adjacent columns of pixels.

2. The display substrate according to claim 1, wherein every at least two adjacent columns of sub-pixels are a cycle period, and the columns of sub-pixels within a same cycle period are electrically connected with discharge wires providing different direct current signals, respectively.

3. The display substrate according to claim 2, wherein the plurality of discharge wires provide two different direct current signals; and
every two adjacent columns of sub-pixels are a cycle period, and the two columns of sub-pixels in a same cycle period are electrically connected with discharge wires providing different direct current signals, respectively.

4. The display substrate according to claim 2, wherein the plurality of discharge wires provide n different direct current signals, n is a total number of all sub-pixels in each pixel, and n is greater than or equal to 3; and
all columns of sub-pixels in each column of pixels are a cycle period, and the columns of sub-pixels in a same cycle period are electrically connected with discharge wires providing different direct current signals, respectively.

5. The display substrate according to claim 2, wherein the plurality of discharge wires provide 2 n different direct current signals, n is a total number of all sub-pixels in each pixel, and n is greater than or equal to 3; and
all columns of sub-pixels in every two adjacent columns of pixels are a cycle period, and the columns of sub-pixels in a same cycle period are electrically connected with discharge wires providing different direct current signals, respectively.

6. The display substrate according to claim 1, wherein the plurality of discharge wires provide two different direct current signals; and
every two adjacent columns of pixels are a cycle period, the two columns of pixels in a same cycle period are electrically connected with discharge wires providing different direct current signals, and columns of sub-pixels in a same column of pixels are electrically connected with discharge wires providing a same direct current signal.

7. The display substrate according to claim 1, wherein the data lines provide data signals with two polarities for columns of sub-pixels in a same column of pixels.

8. The display substrate according to claim 1, further comprising at least two terminals, wherein a same terminal is electrically connected with discharge wires providing a same direct current signal.

9. The display substrate according to claim 8, further comprising at least two filter circuits, wherein the filter circuits are connected between the at least two terminals and the discharge wires providing different direct current signals, respectively.

10. The display substrate according to claim 9, wherein the filter circuit comprises a resistor and a capacitor, wherein the resistor is connected between the terminal and the discharge wire, and the capacitor is connected between the discharge wire and ground.

11. The display substrate according to claim 1, further comprising a gate line, wherein, the second domain area comprises a first transistor and a second transistor, a gate of the first transistor is electrically connected with the gate line, a first electrode of the first transistor is electrically connected with the data line, a second electrode of the first transistor is electrically connected with a first electrode of the second transistor, a gate of the second transistor is electrically connected with the gate line, and a second electrode of the second transistor is electrically connected with the discharge wire; and
ratios of channel width-to-length ratios of first transistors to channel width-to-length ratios of second transistors in adjacent pixels or adjacent sub-pixels in a row direction are different.

12. The display substrate claim 1, wherein in the adjacent pixels or the adjacent sub-pixels in the row direction, the channel width-to-length ratios of the first transistors are same, and the channel width-to-length ratios of the second transistors are different.

13. A display apparatus, comprising the display substrate according to claim 1.
